(19) United States
(12) Patent Application Publication
(10) Pub. No.: US 2015/0263205 A1
(43) Pub. Date: Sep. 17, 2015

(54) CYLINDRICAL SOLAR MODULE AND METHOD OF MAKING THE MODULE

(71) Applicant: TSMC SOLAR LTD., Taichung City (TW)

(72) Inventor: Shih-Wei CHEN, Kaohsiung City (TW)

(73) Assignee: TSMC SOLAR LTD., Taichung City (TW)

(21) Appl. No.: 14/207,767

(22) Filed: Mar. 13, 2014

(51) Int. Cl. H01L 31/0352; H01L 31/18; H01L 31/0203

(52) U.S. Cl. CPC H01L 31/035281; H01L 31/0203; H01L 31/18

(57) ABSTRACT

A solar module comprises a cylindrical substrate, a back contact layer around the substrate, an absorber layer around the back contact layer, a buffer layer around the absorber layer, a front contact layer around the substrate to form a solar module, and a conformal polymer layer encasing the solar module.

### FIELD

This disclosure relates to photovoltaic systems generally, and more specifically to photovoltaic systems including

### BACKGROUND

Photovoltaic cells or solar cells are photovoltaic components for direct generation of electrical current from sunlight. Due to the growing demand for clean sources of energy, the manufacture of solar cells has expanded dramatically in recent years and continues to expand. Solar cells include a substrate, a back contact layer on the substrate, an absorber layer on the back contact layer, a buffer layer on the absorber layer, and a front contact layer above the buffer layer. The layers can be applied onto the substrate during a deposition process using, for example, sputtering and/or co-evaporation.

Semi-conductive materials are used in at least a portion of the absorber layer of some solar cells. For example, chalcopyrite based semi-conductive materials, such as copper indium gallium selenide (CIGS) (also known as thin film solar cell materials), are used to complete the formation of the absorber layer after the deposition process.

Solar cells are typically formed on flat substrates. In recent years, solar cell panels have also been fabricated on cylindrical substrates.

### BRIEF DESCRIPTION OF THE DRAWINGS

FIGS. 1A-1E are isometric views showing stages of fabrication of a solar cell module having a solid cylindrical substrate according to some embodiments.

FIGS. 1F-1J are end views of the device shown in FIGS. 1A-1E, respectively.

FIG. 1K shows the solar cell module of FIGS. 1E and 1J following encapsulation with a conformal polymer coating.

FIGS. 2A-2E are isometric views showing stages of fabrication of a solar cell module having a substrate with thermally conductive fill according to some embodiments.

FIGS. 2F-2J are end views of the device shown in FIGS. 2A-2E, respectively.

FIG. 2K shows the solar cell module of FIGS. 2E and 2J following encapsulation with a conformal polymer coating.

FIGS. 3A-3E are isometric views showing stages of fabrication of a solar cell module having a hollow cylindrical substrate according to some embodiments.

FIGS. 3F-3J are end views of the device shown in FIGS. 3A-3E, respectively.

FIG. 3K shows the solar cell module of FIGS. 2E and 2J following encapsulation with a conformal polymer coating.

FIG. 4 is a diagram of an apparatus for applying a thin film to any of the substrates shown in FIGS. 1A-3J.

FIG. 5A shows a plurality of the solar cell modules connected in parallel.

FIG. 5B shows a plurality of the solar cell modules connected in series.

FIG. 6A shows a fixture for holding a plurality of the solar cell modules connected in parallel during lamination.

FIG. 6B shows a fixture for holding a plurality of the solar cell modules connected in series during lamination.

FIG. 7A shows a row of solar cell modules to be laminated.

FIG. 7B shows the application of polymer sheets to the row of solar cell modules.

FIG. 7C shows the row of solar cell modules after reflowing the polymer sheets.

FIG. 7D shows the laminated solar panel of FIG. 7C, which is flexible is some embodiments.

FIG. 7E is a plan view of the solar panel of FIG. 7D.

FIG. 8A shows convection in a panel of the solar cells according to FIGS. 3A-3J.

FIG. 8B shows heat emission from a panel of the solar cells according to FIGS. 2A-2J.

FIG. 9 is a flow chart showing a method of making a solar cell module.

FIG. 10 is a flow chart of a method of assembling a solar panel from the solar cell modules.

FIG. 11 shows an alternative embodiment of a solar module including interconnect structures having P1, P2 and P3 scribe lines.

FIG. 12 is a flow chart of a method of making a solar cell module shown in FIG. 11.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

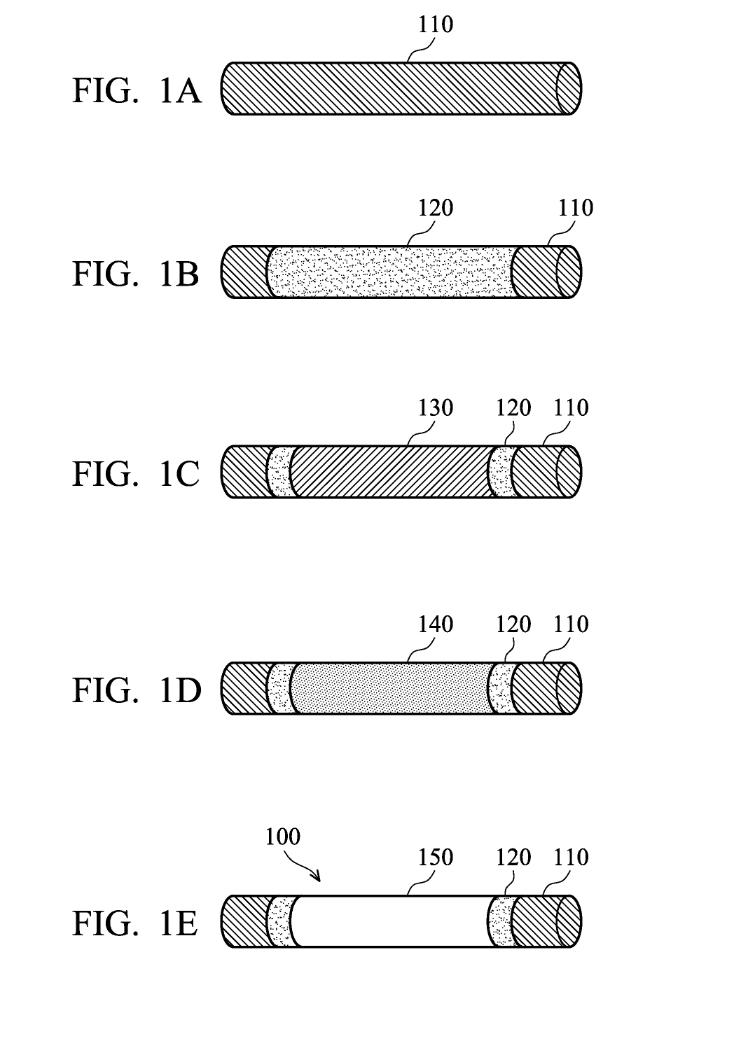

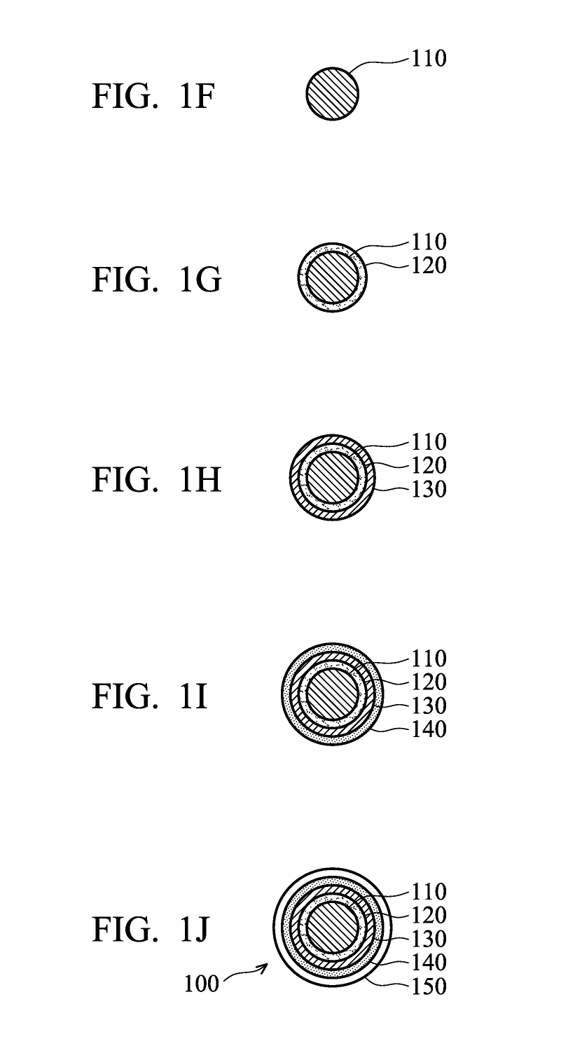

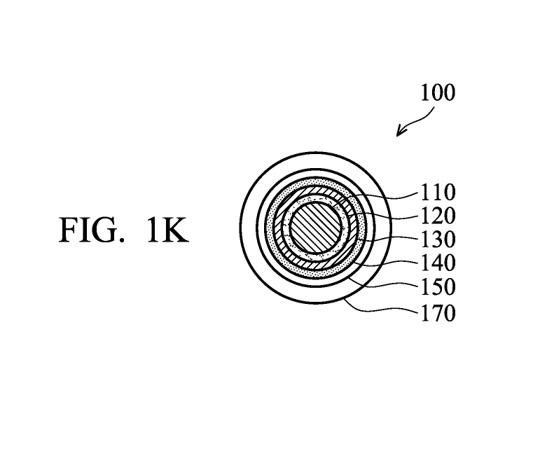

FIGS. 1A to 1J show various steps in the fabrication of a solar module 100. The solar cell module 100 includes a solid cylindrical substrate 110, a back contact layer 120 around the substrate 110, an absorber layer 130 around the back contact layer 120, a buffer layer 140 around the absorber layer 130, and a front contact layer 150 around the buffer layer 140, and a conformal polymer layer 170 encasing the solar module, to form a solar module 100.

FIGS. 1A and 1F show the substrate 110. Substrate 110 is in the form of a solid rod, and can include any suitable substrate material, such as glass. In some embodiments, substrate 110 includes a glass substrate, such as soda lime glass, or a flexible metal foil or polymer (e.g., a polyimide, polyethylene terephthalate (PET), polyethylene naphthalene (PEN)). Other embodiments include still other substrate materials.

FIGS. 1B and 1G show the back contact layer 120 applied around substrate 110. Back contact layer 120 includes any suitable back contact material, such as metal. In some embodiments, back contact layer 120 can include molybdenum (Mo), platinum (Pt), gold (Au), silver (Ag), nickel (Ni), or copper (Cu). Other embodiments include still other back contact materials. In some embodiments, the back contact layer 120 is from about 50 nm to about 2 μm thick. In some embodiments, the back contact layer is formed by sputtering.

FIGS. 1C and 1H show the absorber layer 130 applied around back contact layer 120. In some embodiments, absorber layer 130 includes any suitable absorber material, such as a p-type semiconductor. In some embodiments, the absorber layer 130 can include a chalcopyrite-based material comprising, for example, Cu(In,Ga)Se2 (CIGS), cadmium telluride (CdTe), CuInSe2 (CIS), CuGaSe2 (CGS), Cu(In,Ga)Se2 (CIGS), Cu(In,Ga)(Se,S)2 (CIGSS), CdTe or amorphous silicon. Other embodiments include still other absorber materials. In some embodiments, the absorber layer 130 is from about 0.3 μm to about 3 μm thick. The absorber layer 130 can be applied using a variety of different process. For example, the CIGS precursors can be applied by sputtering. In other embodiments, one or more of the CIGS precursors are applied by evaporation.

FIGS. 1D and 1I show the buffer layer 140 applied around back absorber layer 130. Buffer layer 140 includes any suitable buffer material, such as n-type semiconductors. In some embodiments, buffer layer 140 can include cadmium sulphide (CdS), zinc sulphide (ZnS), zinc selenide (ZnSe), indium(III) sulfide (In2S3), indium selenide (In2Se3), or Zn1-xMgxO, (e.g., ZnO). Other embodiments include still other buffer materials. In some embodiments, the buffer layer 140 is from about 1 nm to about 500 nm thick. In some embodiments, the buffer layer 140 is applied by a wet process, such as chemical bath deposition (CBD).

FIGS. 1E and 1J show the front contact 150 applied around back buffer layer 140. In some embodiments, front contact layer 150 includes an annealed transparent conductive oxide (TCO) layer. In some embodiments, the TCO layer 150 is highly doped. For example, the charge carrier density of the TCO layer 150 can be from about 1×10¹⁷ cm⁻³ to about 1×10¹⁸ cm⁻³. The TCO material for the annealed TCO layer can include any suitable front contact material, such as metal oxides and metal oxide precursors. In some embodiments, the TCO material can include zinc oxide (ZnO), cadmium oxide (CdO), indium oxide (In₂O₃), tin dioxide (SnO2), tantalum pentoxide (Ta₂O₅), gallium indium oxide (GaInO₃), (CdSb₂O₃), or indium oxide (ITO). The TCO material can also be doped with a suitable dopant. In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO2 can be doped with antimony (Sb), F, As, niobium (Nb), or tantalum (Ta). In other embodiments, In2O3 can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants. In some embodiments, the front contact layer 110 is from about 5 nm to about 3 μm thick. In some embodiments, the front contact layer 150 is formed by metal organic chemical vapor deposition (MOCVD). In other embodiments, the front contact 150 is formed by sputtering.

FIG. 1K shows the encapsulating polymer layer 170 applied around the front contact layer 150. The encapsulating polymer can comprise ethylene vinyl acetate (EVA). In some embodiments, the polymer 170 is applied to individual solar modules 100. An individually encapsulated solar module 100 has an outer diameter of about 0.05 m to about 0.06 m.

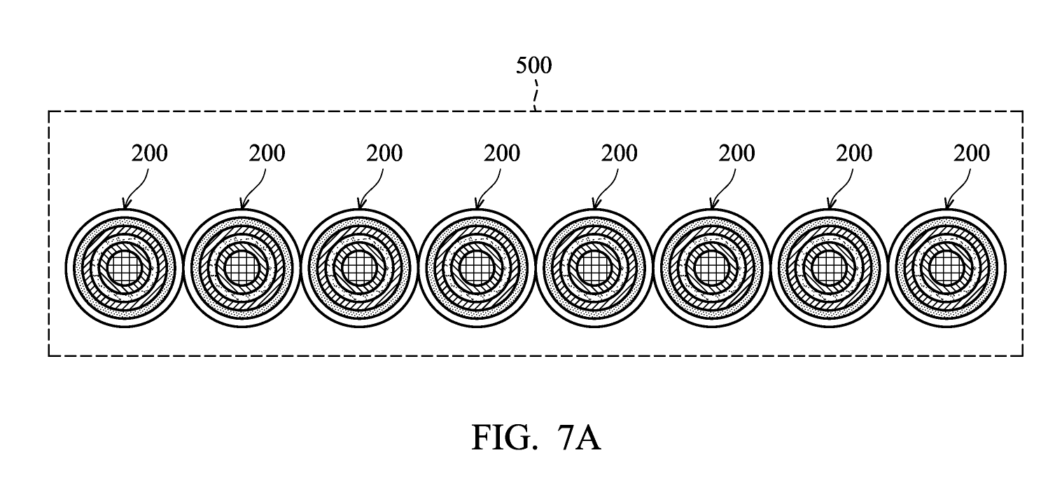

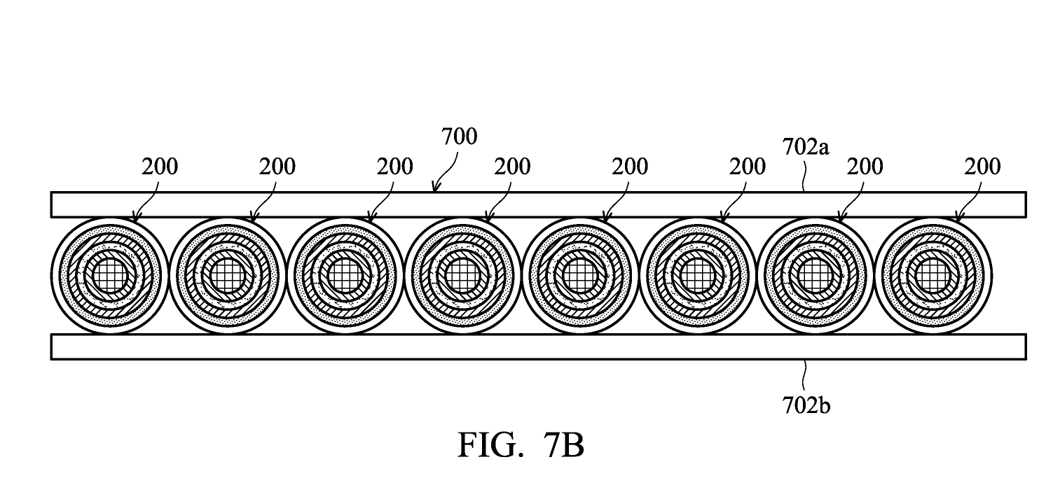

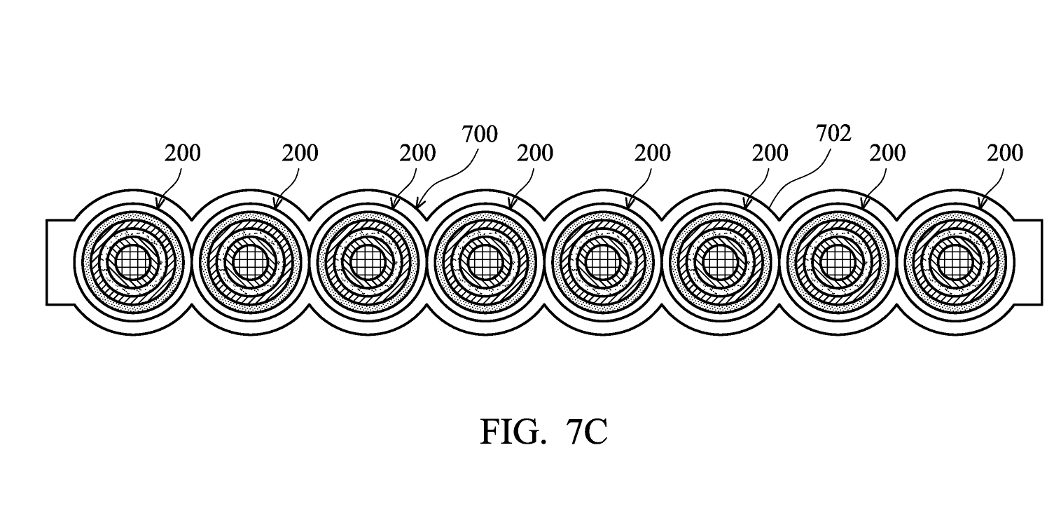

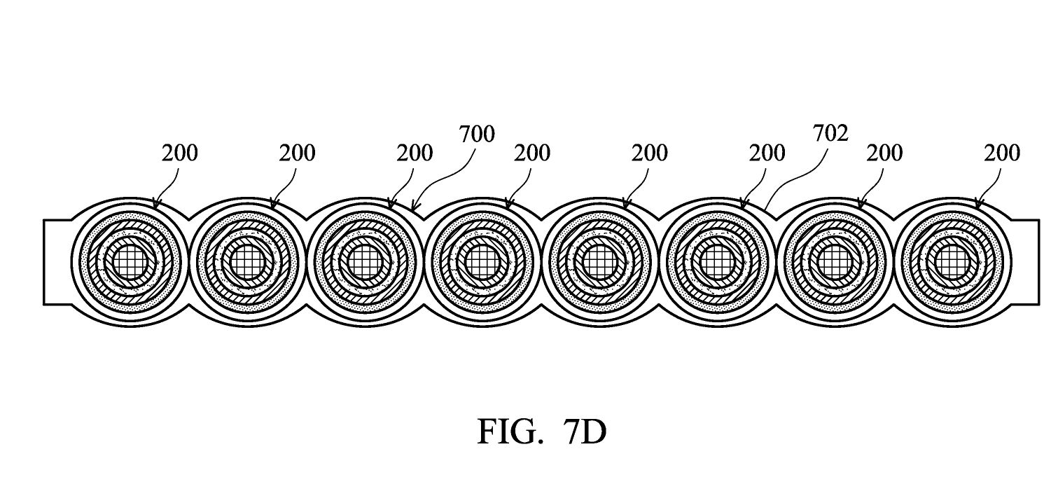

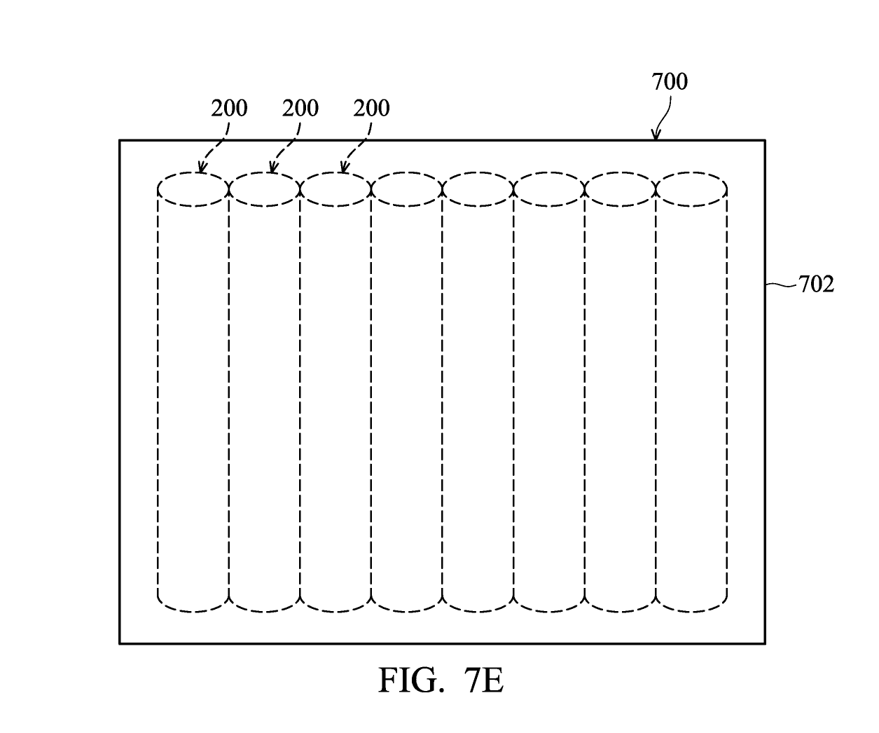

In other embodiments, the polymer 170 is laminated onto an array of solar modules 100 to form a solar panel, as described in the discussion of FIGS. 7A-7D below.

The solar cell module 100 is configured as an elongated cylinder or rod with a longitudinal axis. In some embodiments, the layers 120, 130, 140, 150 are arranged so that the back contact 120 extends beyond the front contact 150 on at least one end of the solar cell module 100. In some embodiments, the back contact 120 extends beyond the front contact 150 at both ends of the solar cell module 100. Thus, in the configuration shown, the areas in which the back electrode 120 are exposed allow interconnections between cells to be formed, without requiring the scribe line (P1, P2, P3) interconnections between adjacent cells.

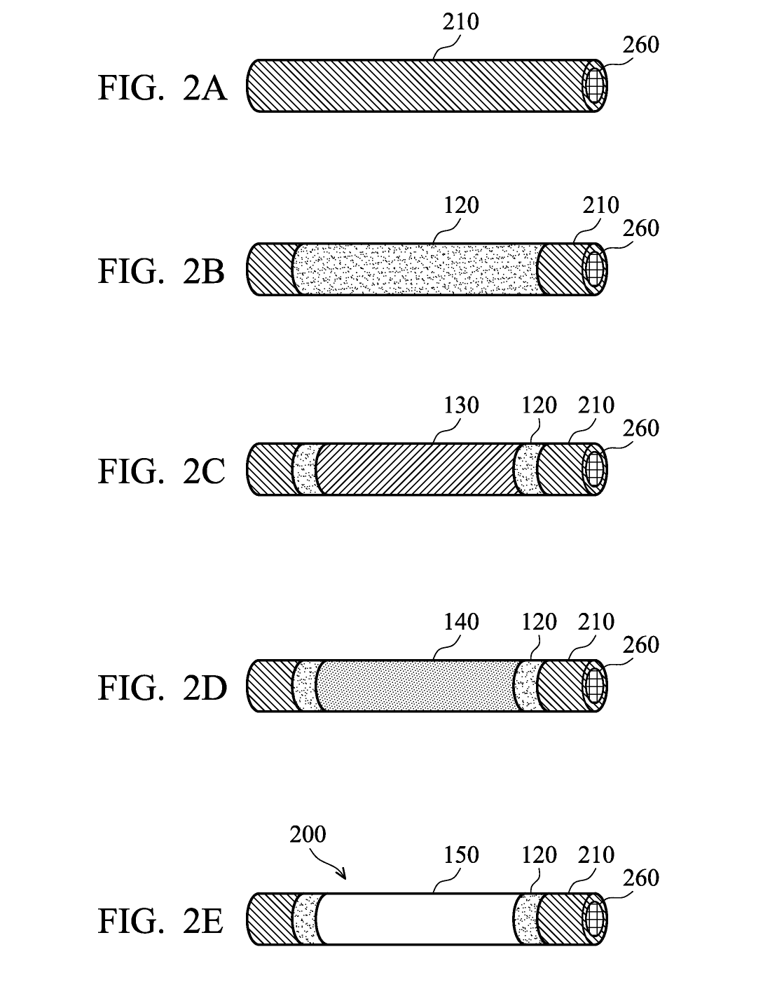

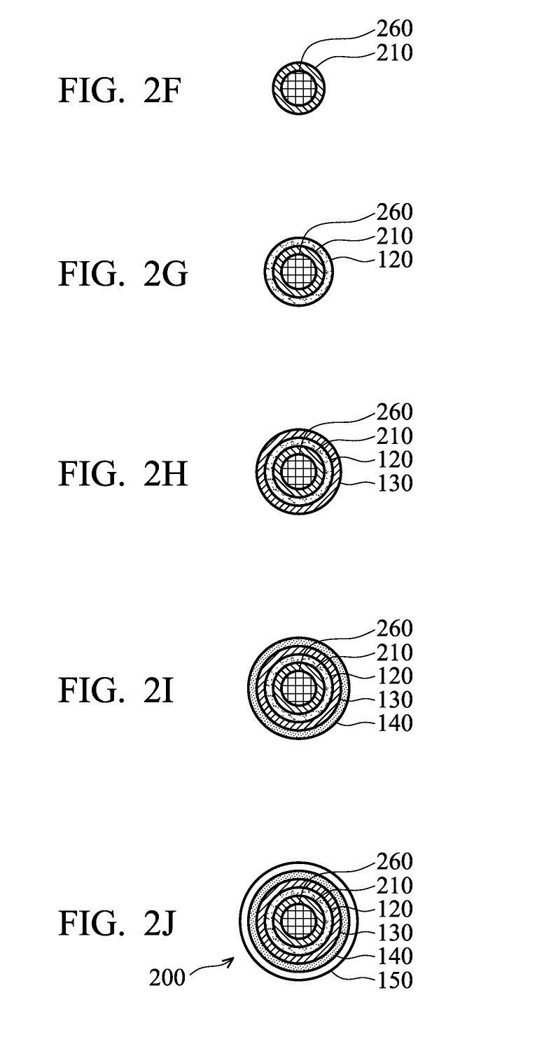

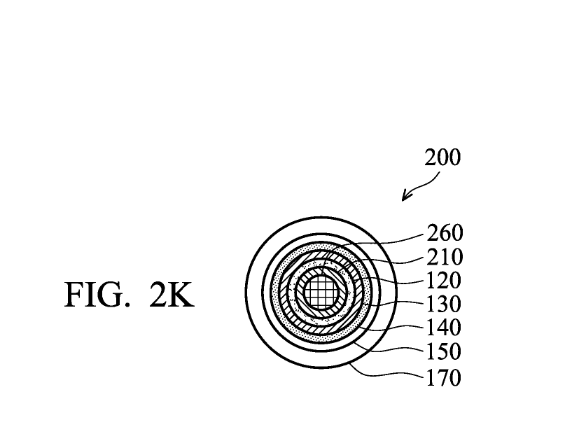

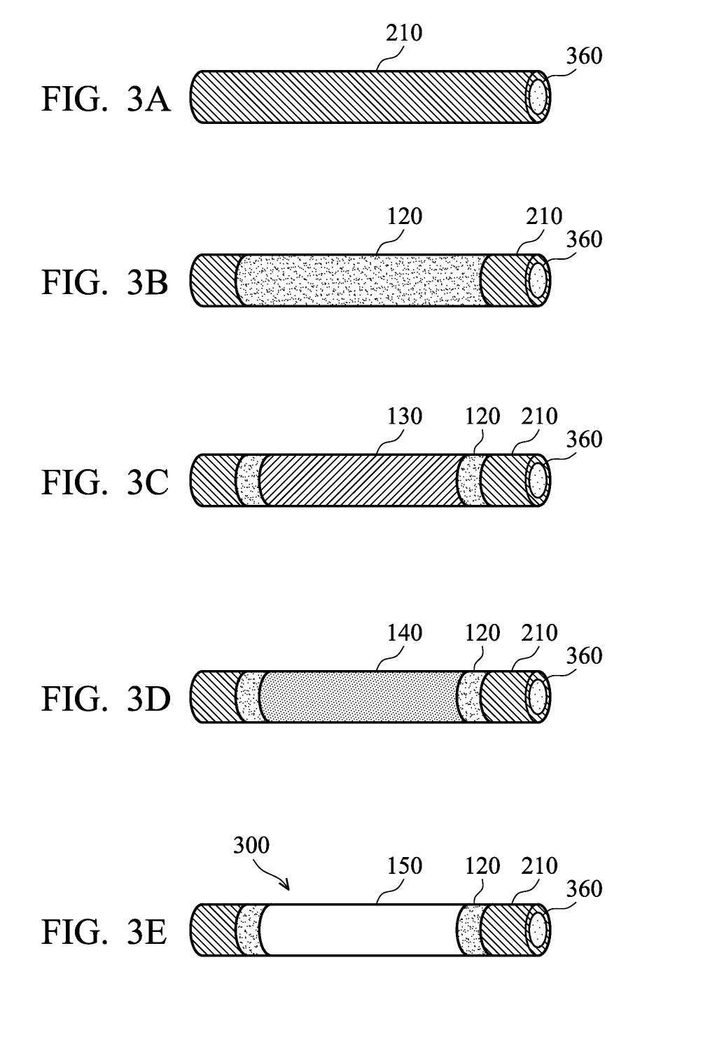

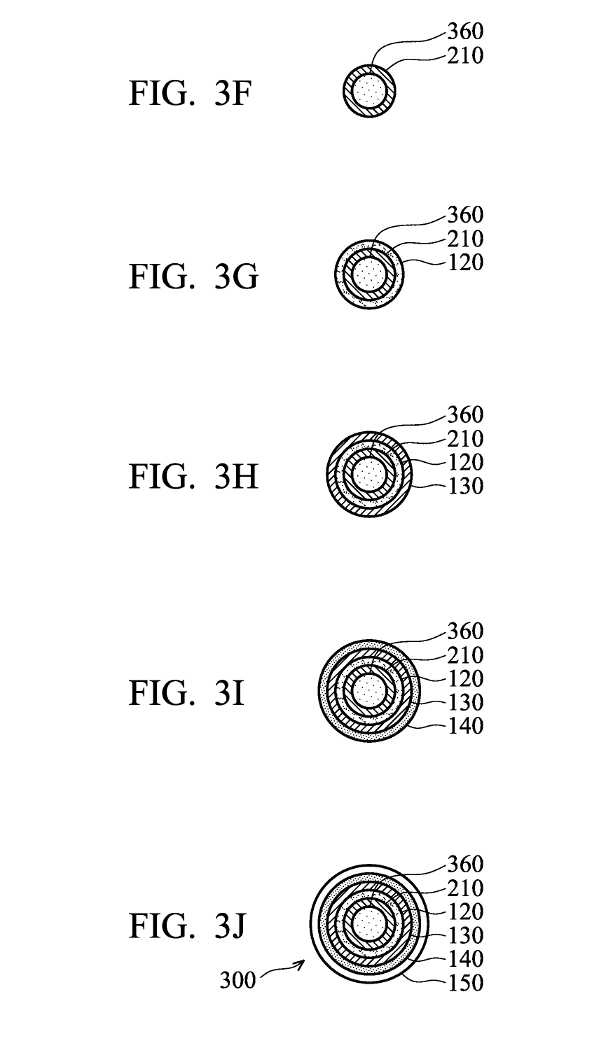

FIGS. 2A-2K show an embodiment of the solar cell module 200, wherein the substrate comprises a hollow tube 210 and a thermally conductive material 260 filling the hollow tube. The thermally conductive material spreads heat throughout the length of the solar module 200.

Referring to FIGS. 2A and 2F, In some embodiments, the hollow tube 210 comprises soda lime glass, and the thermally conductive material comprises Al₂O₃, thermal grease, an oxide, a nitride or the like. In other embodiments, the hollow tube 210 can comprise a high strength glass or a polymer, and the thermally conductive material can be a nitride or oxide material. The thermally conductive material has a melting point higher than the temperatures at which the thin film layers 120, 130, 140 and 150 are applied. The hollow tube 210 is filled with the thermally conductive material 260 using a bulk fill process.

The remaining FIGS. 2B-2E and 2G-2K show the formation of the back contact 120, absorber 130, buffer layer 140 and front contact 150. These layers can have the same materials and configurations as described above with respect to corresponding FIGS. 1B-1E and 1G-1K, and can be formed by the same processes. For brevity, the above descriptions are not repeated.

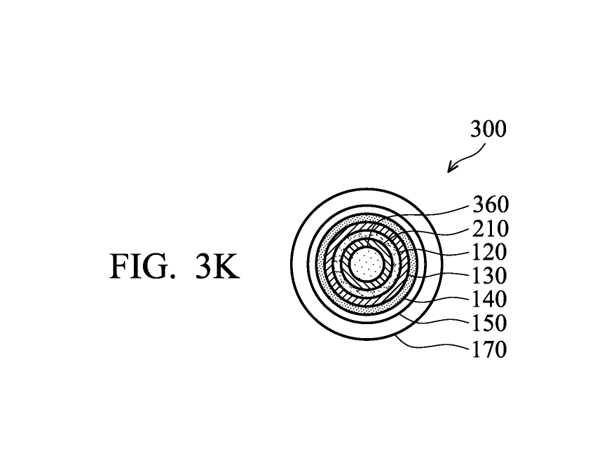

FIGS. 3A-3K show an embodiment of the solar cell module 300, wherein the substrate 210 is a hollow cylindrical tube without any fill material, and the conformal polymer is excluded from an interior of the hollow cylindrical tube. In some embodiments, the hollow tube 210 comprises soda lime glass. In other embodiments, the hollow tube 210 can comprise a high strength glass or a polymer. The hollow tube 210 permits convection (e.g., natural convection or forced convection) to cool the inside of the solar module 300. In some embodiments, the inner diameter of the hollow tube 210 is in a range from about 0.5 cm to about 5 cm. In some embodiments, the outer diameter of the hollow tube 210 is in a range from about 0.7 cm to about 5.2 cm.

FIGS. 3B-3E and 3G-3K show the formation of the back contact 120, absorber 130, buffer layer 140 and front contact 150. These layers can have the same materials and configurations as described above with respect to corresponding FIGS. 1B-1E and 1G-1K, and can be formed by the same processes. For brevity, the above descriptions are not repeated.

The solar modules 100, 200, 300 can be made of the same materials as flat solar panels (not shown), and thus the thin films can be deposited with equipment similar to the equipment

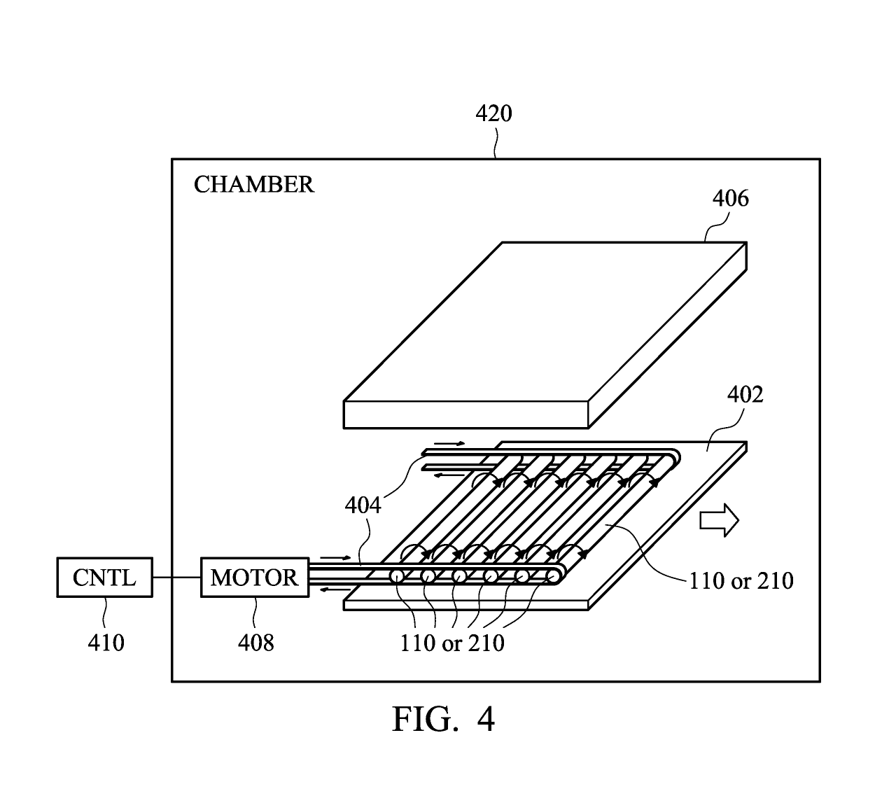

FIG. 4 is a schematic diagram of a tool for holding and rotating the substrates 110, 210 during various thin film deposition steps in the fabrication of the solar cells of FIG. 1K, 2K or 3K. A plurality of substrates 110 or 210 are arranged on a carrier 402 which is movable within a deposition chamber 420 for depositing any of the layers 120, 130, 140 or 150. The carrier 402 is equipped with a rotating drive mechanism, 404, which can include a drive belt (coupled to a motor 408), a timing belt (coupled to a motor), or a gear train (coupled to a motor). The drive mechanism is controlled by a controller 410, to rotate the substrates 110, 210 at a uniform rate sufficiently fast to provide uniform film thickness throughout the circumference of each film layer 120, 130, 140, 150. In some embodiments, the controller 410 can also control the translation speed of the carrier 402. By controlling both the translation speed of the carrier 402 and the rotation speed of the substrates 110, 210, the controller can ensure that each substrate rotates a desired number of times during the deposition, to provide uniform thickness of the films on the substrates.

For example, in some embodiments, the controller 410 receives the total processing time as an input. The controller 410 can divide the processing time into an integer number of rotations, and set the rotation speed of the motor 408 to rotate an integer number of times during thin film application. This ensures uniform exposure to the flow or material being deposited throughout the circumference of the solar module 110 or 210.

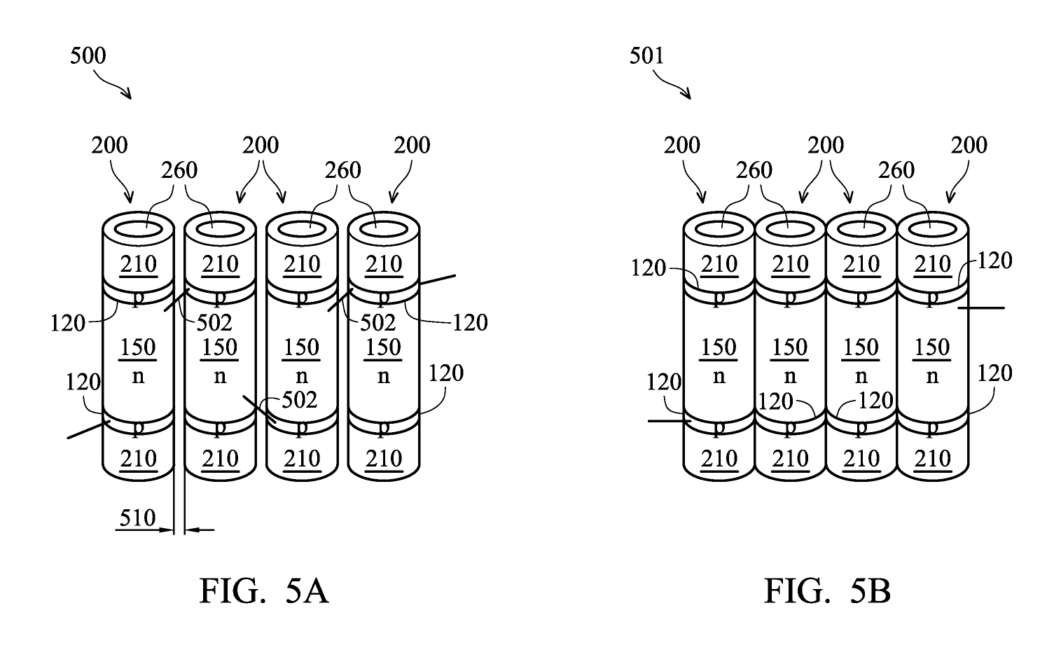

FIGS. 5A and 5B are schematic diagrams showing interconnection methods for connecting a plurality of the solar modules 100, 200 or 300 described above to form a solar panel 500 (or 501). Although FIGS. 5A and 5B show solar modules 200, solar modules 100 or 300 can be configured in the same fashion.

In some embodiments, a plurality of solar modules 200 are connected in parallel, as shown in FIG. 5A. The solar modules 200 are isolated from each other, for example, by the encapsulating polymer layer 170 (not shown in FIG. 5A). Each pair of adjacent solar modules 200 are separated from each other by a distance of about 1 mm or more. A conductor 502 connects a front electrode 150 of a first one of the solar modules 200 to a back electrode 120 of a second one of the solar modules adjacent to the first solar module. In embodiments in which the front contact 150 is n-doped, and the back contact 120 is p-doped, the solar modules 200 are thus interconnected to form a p-n-p-n device.

The conductor 502 is subsequently encased within the conformal polymer layer 170 at the same time as the rest of the solar module 200. The conformal polymer material 170 fills the space between solar modules 200. By connecting a plurality of solar modules 200 in parallel, a higher open circuit voltage Voc is obtained. Also, each solar module 200 can absorb light for generating electricity throughout the circumference of the module, including the surfaces facing the spaces between adjacent solar modules. Thus, the spacing 510 between adjacent solar modules permits additional light to reach the surfaces facing directly towards the adjacent solar module.

In some embodiments, a plurality of solar modules 200 are connected in series, as shown in FIG. 5B. The solar modules 200 abut each other in direct contact, so that the front conductors 150 of each pair of adjacent solar modules are conductively coupled to each other, and the back conductors 120 of each pair of adjacent solar modules are conductively coupled to each other. Optionally, a first set of wires can connect the back electrodes together, and a second set of wires can connect the front electrodes together. The conductor 502 is subsequently encased within the conformal polymer layer 170 at the same time as the rest of the solar module 200. In the configuration of FIG. 5B, the plurality of abutting solar modules 200 form a p-n junction.

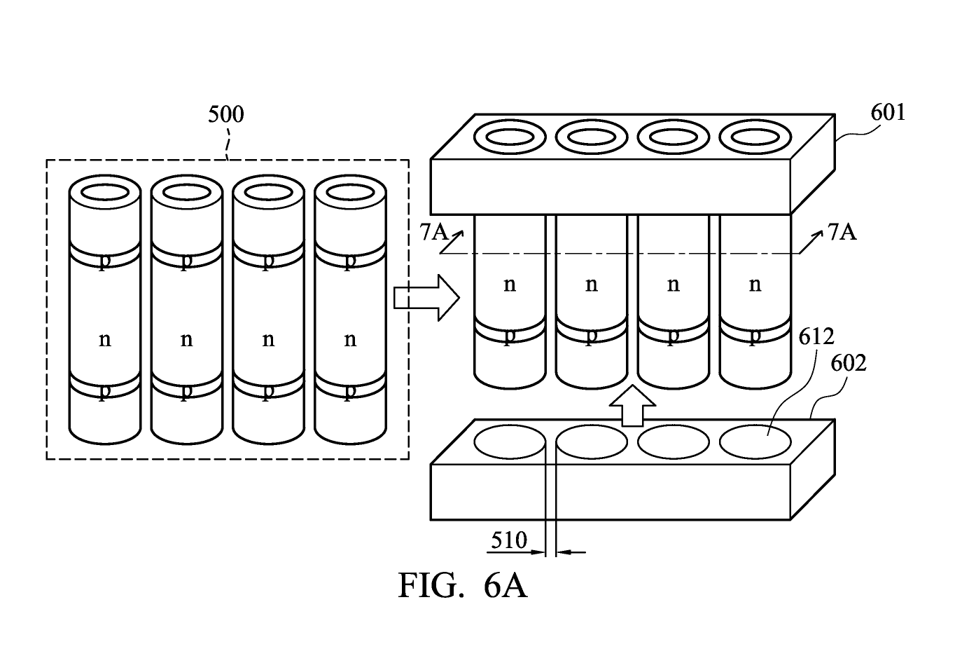

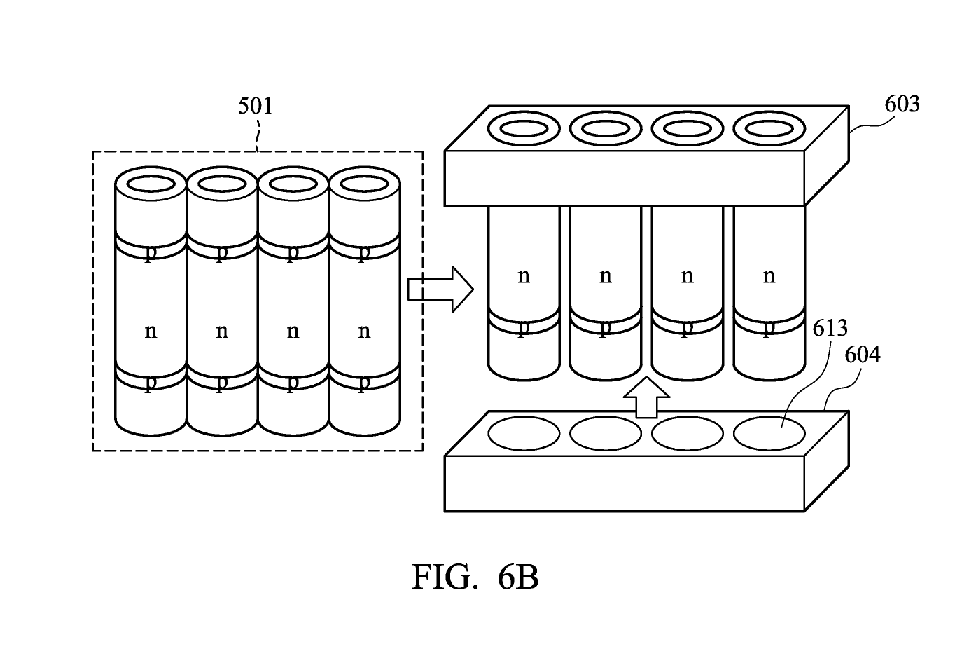

FIG. 6A shows a method of fixing a set 500 of solar modules in preparation for applying the polymer layer 170. The solar modules 200 can also be fixed during the application of the wirings shown in FIG. 5A. A respective end cap 601, 602 is applied at each end of the array 500. The end caps 601, 602 include spaced openings 612 adapted to receive respective ends of each solar module. The openings 612 define a predetermined spacing 510 between adjacent ones of the solar modules 200 in the set 500. For example, in some embodiments, the spacing 510 is 1 mm or more.

The set 500 of solar modules remains within the end caps 601, 602 throughout the encapsulation process. In some embodiments, the end caps 601, 602 include seals, such as O-ring seals (not shown), to prevent the back contact 120, absorber 130, buffer 140 or front contact 150 materials from being deposited on the end of the cylinder 110, 210, or inside the cylinder (for embodiments including a hollow cylinder 210). In some embodiments, the end caps 601, 602 remain on the ends of the solar array 500 following assembly, for protection. In other embodiments, the end caps 601, 602 are removed after encapsulation, and reused.

FIG. 6B shows a similar set of end caps 603, 604 used to fix a set 501 of solar modules 200 in preparation for applying the polymer layer 170. A respective end cap 603, 604 is applied at each end of the array 501. The end caps 603, 604 include abutting openings adapted to receive respective ends of each solar module 200, and keep the solar modules aligned in the longitudinal direction, and in direct contact with adjacent solar modules.

Although FIGS. 6A and 6B show solar modules 200, solar modules 100 or 300 can be fixed in the same fashion.

FIGS. 7A-7D show an example of a method for encapsulating an array of the solar modules 100, 200 or 300. Although solar modules 200 are shown, the same method can be applied to modules 100 or 300. Although the example shows a parallel set 500 of solar modules 200, the same method can be used for a set 501 of solar modules 100, 200 or 300 connected in series.

FIG. 7A is a cross sectional view taken along section line 7A-7A of FIG. 6A. FIG. 7A shows an array of the solar modules. The array can include any desired number for a solar panel. The solar modules 200 have been fixed in end caps 601 and 602 for parallel connected solar modules (or end caps 603 and 604 for series connected solar modules).

FIG. 7B shows the application of two sheets 702a, 702b of a polymer material, such as EVA. In some embodiments, the thickness of the polymer sheets is in a range from about 0.2 mm to about 0.5 mm. Preferably, the length and width of the sheets 702a, 702b is greater than the width of the array 500 of modules 100, 200 or 300 and the length of each module, respectively. This allows the film to fill in the spaces between modules during the lamination process. In some embodiments, during lamination, the vacuum and heating are applied sequentially. In other embodiments, the vacuum and heating are applied simultaneously. In some embodiments, the laminator includes a chamber with vacuum, heating and pressing capability. A conveyor transfers the panel into the vacuum chamber and the pressure is set within a range from about 10 torr to about 500 torr, and then a force is applied to laminate the module. FIG. 7C shows the assembly at the completion of the vacuum process.

The polymer sheets 702a, 702b are then subjected to heat and pressure to reflow the polymer to conform to the exterior shapes of the solar modules, and completely encapsulate the solar modules. In some embodiments, the polymer sheets 702a, 702b are heated to a temperature in a range from about 120 degrees C. to about 140 degrees C. The final solar array 700 is shown in FIGS. 7D and 7E.

FIGS. 7D and 7E show the encapsulated solar array 700 after completion of the lamination. In some embodiments (not shown), the thickness of the polymer sheets 702a, 702b is sufficient, so that the laminated assembly is encased in a flat polymer casing formed from the reflowed sheets 702a, 702b. The continuous conformal polymer layer 702 encases the at least two solar modules 200. The polymer casing 702 protects the active areas of the solar modules 200.

Following reflowing of the polymer material, the solar panel 500 can be removed from the processing chamber, and the end caps 601, 602 (or 603, 604) are removed. The resulting solar panel 700 does not need a separate frame for structural support.

In some embodiments, the polymer of the casing 702 is capable of elastic bending. In some embodiments, the polymer has a modulus of elasticity of about 0.0110 GPa or less.

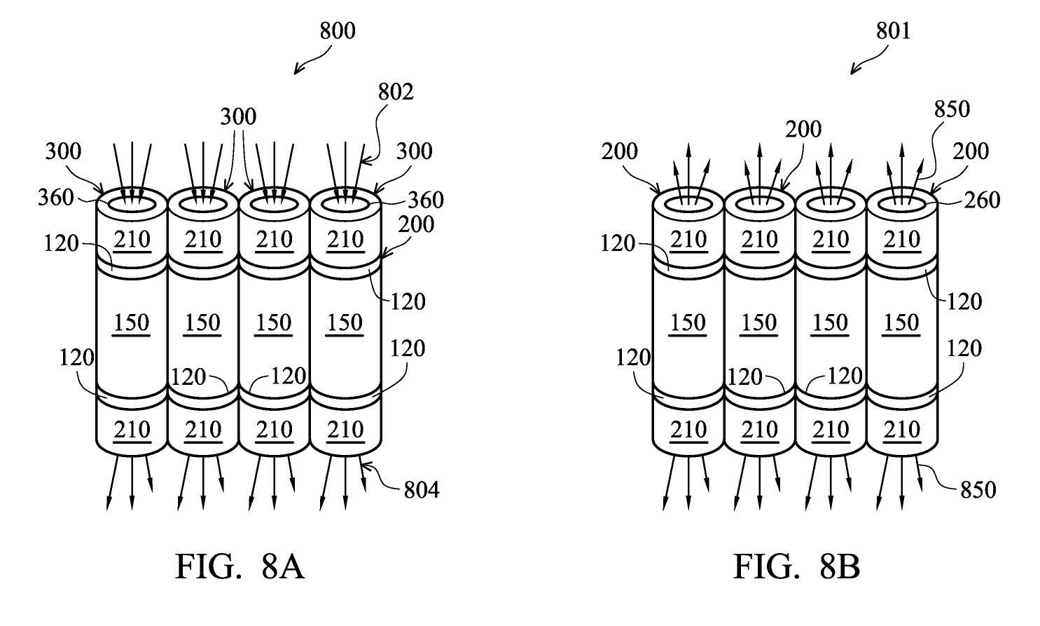

FIG. 8A shows a portion of a solar panel 800 including the solar modules 300. The encapsulating polymer 170 is omitted from FIG. 8A for ease of illustration, but is present in the finished solar panel 800. Each module 300 has a hollow substrate 210, with a cylindrical hole 360 therethrough. The cylindrical holes 360 permit air to flow through the solar panel 800, for a lower and more uniform temperature distribution, enhancing performance. Thus, air enters the holes 360 as shown by arrows 802, and exits the holes, as shown by arrows 804.

FIG. 8B shows a portion of a solar panel 801 including the solar modules 200. The encapsulating polymer 170 is omitted from FIG. 8B for ease of illustration, but is present in the finished solar panel 801. Each module 200 has a hollow substrate 210, with a cylindrical hole filled with thermally conductive material 260. The thermally conductive material 260 spreads heat through each solar module 200 in the solar panel 801, for a lower and more uniform temperature, enhancing performance. Thus, heat is conducted to the ends of each solar module 200 and the ends of the solar modules 200 expel heat from both ends (by convection) as shown by arrows 850.

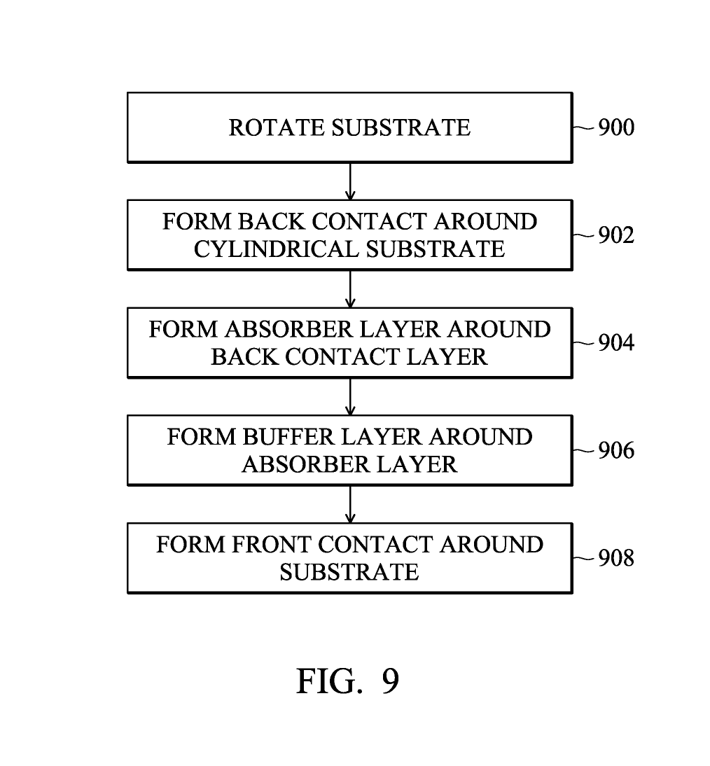

FIG. 9 is a flow chart of an alternative method of making a solar module 100, 200 or 300. According to some embodiments, interconnections between modules are made by wirings 502 connecting the front contact of one solar module 100, 200, 300 to the back contact of an adjacent solar module, without the need for scribe line interconnect structures.

At step 900, at least one substrate 110 or 210 is rotated within a deposition chamber 420, for example by rotating a plurality of substrates 110 on a carrier 402, using an automatically controlled belt drive 404. At least one of the subsequent steps of forming the back contact, forming the absorber layer or forming the front contact layer includes rotating the substrate during the forming. By rotating the substrate during thin film deposition, a uniform film thickness can be achieved.

At step 902, a back contact layer 120 is formed over a solar cell substrate. In some the back contact layer 120 can deposited by sputtering a metal such as molybdenum over the solar cell substrate 110 or 210.

At step 904, the absorber layer 130 is formed over the back contact 120. The bottom of absorber layer 130 contacts the back contact layer 120. In some embodiments, the absorber comprises CIGS. In some embodiments, a plurality of CIGS precursors are sputtered onto the back contact layer 120. In some embodiments, the CIGS precursors include Cu/In, CuGa/In and/or CuInGa, applied by sputtering. The absorber layer material fills the P1 scribe line. Following the sputtering of these precursors, selenization is performed.

At step 906, the buffer layer 140 is formed over the absorber layer 130. For example, in some embodiments, a layer of CdS, ZnS or InS is formed by chemical bath deposition (CBD). In other embodiments, the buffer layer 140 is deposited by sputtering or atomic layer deposition (ALD).

At step 908, the front contact layer 150 is formed over the buffer layer. In some embodiments, the front contact layer 150 is i-ZnO or AZO applied by sputtering. In other embodiments, the front contact layer 150 is BZO applied by metal organic chemical vapor deposition (MOCVD).

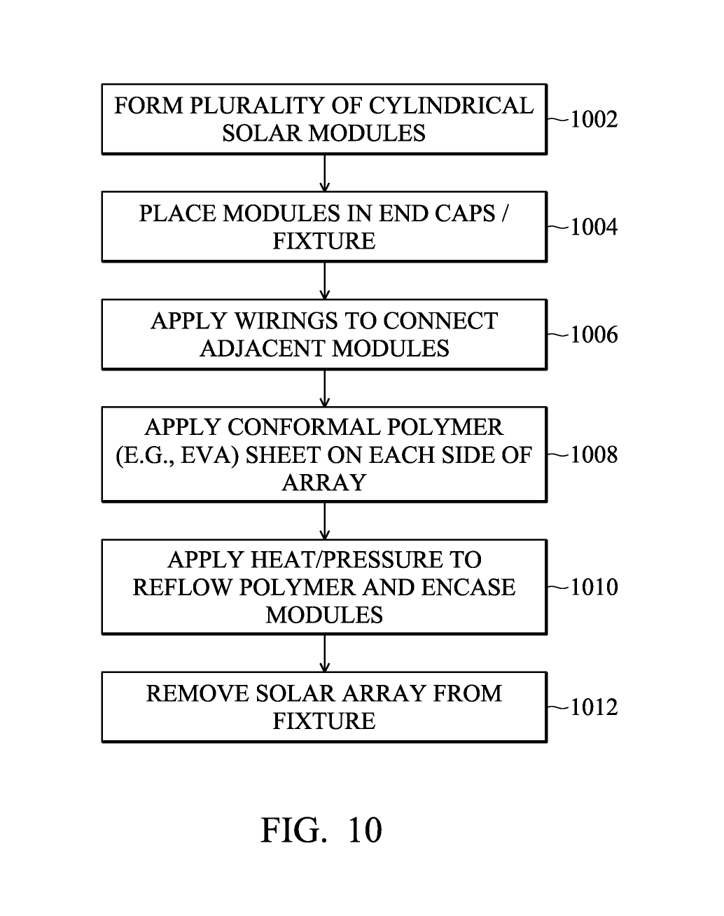

In some embodiments, after step 908, the solar modules 100, 200, or 300, are encapsulated individually to achieve the configurations shown in FIG. 1K, 2K or 3K. For example, in some embodiments, one or more polymer sheets are laminated around the solar module, and the solar module is heated to reflow the conformal polymer around the solar module. In other embodiments, a plurality of solar modules 100, 200 or 300 are interconnected by wirings connecting the front contact layer 150 of a first solar module to the back contact layer 120 of an adjacent solar module, as discussed below in the description of FIG. 10.

FIG. 10 is a flow chart of a method for interconnecting and encapsulating a plurality of solar modules.

In step 1002 of FIG. 10, a plurality of cylindrical solar modules 100, 200 or 300 are formed, and arranged to form an array 500 as shown in FIG. 6A (or array 501 as shown in FIG. 6B).

At step 1004, a respective end cap 601, 602 is applied at each end of the array 500, as shown in FIG. 6A for parallel connected solar modules (or as shown in FIG. 6B for series connected modules). The end caps 601, 602 include spaced openings 612 adapted to receive respective ends of each solar module 100, 200, 300. The openings 612 define a predetermined spacing 510 between adjacent ones of the solar modules 100, 200 or 300.

In step 1006, if the solar modules are to be connected in parallel, wirings 502 are applied to connect the front contact 150 of a first solar module to a back contact 120 of an adjacent solar module, as shown schematically in FIG. 5A.

At step 1008, a conformal polymer layer is applied. In some embodiments, this step includes laminating one or more polymer sheets 702a, 702b around the array 500 of solar modules 100, encasing the solar modules.

At step 1010, the array 500 of solar modules is heated to reflow the conformal polymer 702a, 702b around the solar module to form a continuous conformal coating 702 encasing the solar modules 100, 200, or 300.

At step 1012, in some embodiments, the end caps 601, 602 are removed after the laminating. In other embodiments, the end caps 601, 602 can be retained on the solar array 500 for protection after lamination is completed.

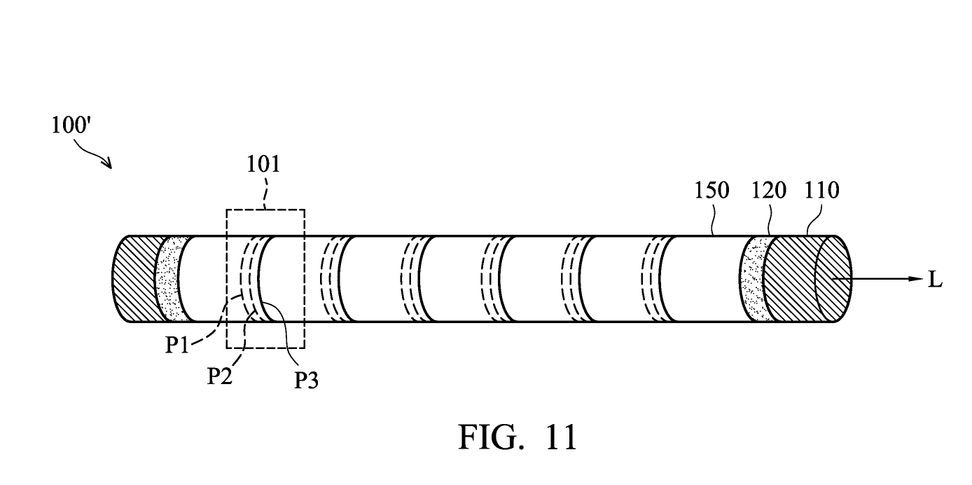

In an alternative embodiment, as shown in FIG. 11, the solar module 100′ has a plurality of solar cells 101. Each Solar cell 101 includes the back contact 120, absorber 130, buffer 140 and front contact 150 layers. Each solar cell 101 also includes interconnect structures that include three scribe lines, referred to as P1, P2, and P3. The P1 scribe line extends through the back contact layer 120 and is filled with the absorber layer material. The P2 scribe line extends through the buffer layer 140 and the absorber layer 130 and is filled with the front contact layer material. The P3 scribe line extends through the front contact layer 150, buffer layer 140 and absorber layer 130. The P1, P2 and P3 scribe lines form series interconnections between each pair of adjacent solar cells 101 in the longitudinal direction L. Thus, any desired number of individual solar cells 101 can be connected in series on a single substrate 110. Two or more of the solar modules 100′ can be connected in the manner shown in FIG. 5A, and described above.

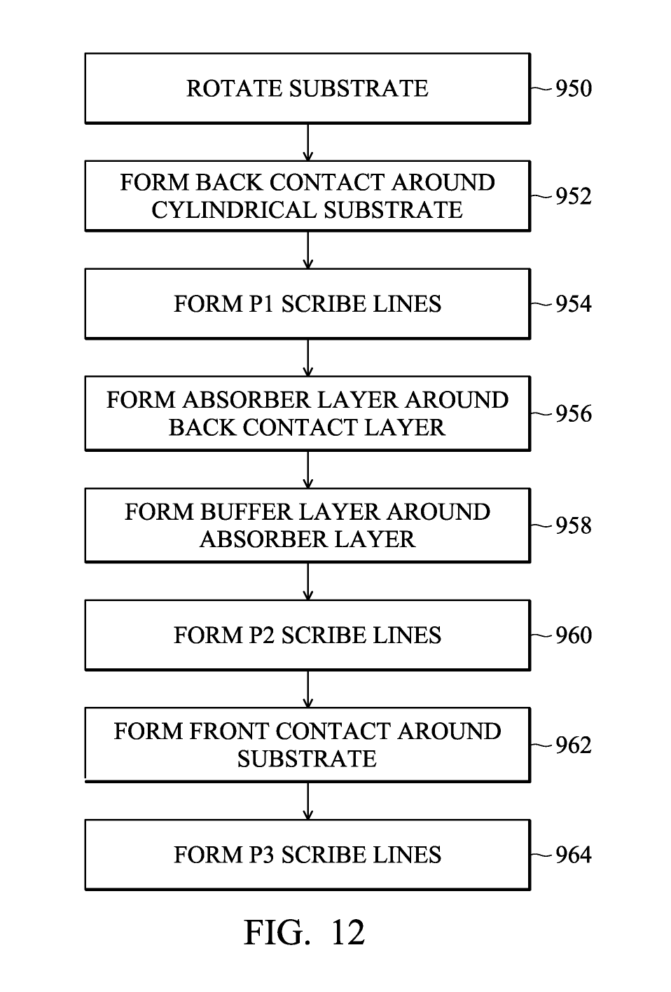

FIG. 12 is a flow chart of an alternative method of making a solar module 100′ having scribe line interconnect structures to connect adjacent solar modules, as shown in FIG. 11.

At step 950, at least one substrate 110 or 210 is rotated within a deposition chamber 420, for example by rotating a plurality of substrates 110 on a carrier 402, using an automatically controlled belt drive 404. At least one of the subsequent steps of forming the back contact, forming the absorber layer or forming the front contact layer includes rotating the substrate during the forming. By rotating the substrate during thin film deposition, a uniform film thickness can be achieved.

At step 952, a back contact layer 120 is formed over a solar cell substrate. In some the back contact layer 120 can deposited by sputtering a metal such as molybdenum over the solar cell substrate 110 or 210.

At step 954, at the conclusion of back contact layer deposition, the P1 scribe line is formed (e.g., scribed or etched) through the back contact layer 120.

At step 956, the absorber layer 130 is formed over the back contact 120. The bottom of absorber layer 130 contacts the back contact layer 120. In some embodiments, the absorber comprises CIGS. In some embodiments, a plurality of CIGS precursors are sputtered onto the back contact layer 120. In some embodiments, the CIGS precursors include Cu/In, CuGa/In and/or CuInGa, applied by sputtering. The absorber layer material fills the P1 scribe line. Following the sputtering of these precursors, selenization is performed.

At step 958, the buffer layer 140 is formed over the absorber layer 130. For example, in some embodiments, a layer of CdS, ZnS or InS is formed by chemical bath deposition (CBD). In other embodiments, the buffer layer 140 is deposited by sputtering or atomic layer deposition (ALD).

At step 960, following the deposition of the buffer layer 140, the P2 scribe line is formed (e.g., scribed or etched) through the absorber layer 130 and buffer layer 140.

At step 962, the front contact layer 150 is formed over the buffer layer. In some embodiments, the front contact layer 150 is i-ZnO or AZO applied by sputtering. In other embodiments, the front contact layer 150 is BZO applied by metal organic chemical vapor deposition (MOCVD). The front contact layer material conformally coats the side and bottom walls of the P2 scribe line.

At step 964, following deposition of the front contact layer 150, the P3 scribe line is formed (e.g., scribed or etched) through the front contact layer 150, buffer layer 140, and absorber layer 130.

A plurality of the solar modules 100′ can be assembled into a solar array, in a manner similar to that described above with reference to FIG. 10. Since each solar cell module 100′ has internal interconnect structures (in scribe lines P1, P2, P3), the interconnections between modules are made to connect the front contact of the last cell of a first solar module to the back contact of the first cell of an adjacent second solar module.

In some embodiments, a solar module comprises a cylindrical substrate, a back contact layer around the substrate, an absorber layer around the back contact layer, a buffer layer around the absorber layer, a front contact layer around the substrate to form a solar module, and a conformal polymer layer encasing the solar module.

In some embodiments, the substrate is a solid rod.

In some embodiments, the substrate is a hollow cylindrical tube, and the conformal polymer is excluded from an interior of the hollow cylindrical tube.

In some embodiments, the substrate comprises a hollow tube and a thermally conductive material filling the hollow tube.

In some embodiments, the tube comprises soda lime glass, and the thermally conductive material comprises Al₂O₃.

In some embodiments, a solar panel comprises at least two solar modules, each solar module comprising, a cylindrical substrate, a back contact layer around the substrate, an absorber layer around the back contact layer, a buffer layer around the absorber layer, and a front contact layer around the substrate; and a continuous conformal polymer layer encasing the at least two solar modules.

In some embodiments, each substrate is a solid rod.

In some embodiments, each substrate is a hollow cylindrical tube, and the conformal polymer is excluded from an interior of each hollow cylindrical tube.

In some embodiments, each substrate comprises a hollow tube and a thermally conductive material filling the tube.

In some embodiments, each tube comprises soda lime glass, and the thermally conductive material comprises Al₂O₃.

Some embodiments further comprise a conductor connecting a front electrode of a first one of the solar modules to a back electrode of a second one of the solar modules adjacent to the first solar module, the conductor encased within the conformal polymer layer.

In some embodiments, each adjacent pair of solar modules within the at least two solar modules are separated from each other by a space, and the conformal polymer material fills the space.

In some embodiments, two solar modules within the at least two solar modules have the front electrodes thereof contacting each other.

In some embodiments, a method comprises forming a back contact layer around a cylindrical substrate; forming an absorber layer around the back contact layer; forming a buffer layer around the absorber layer; forming a front contact layer around the substrate to form a solar module; and applying a conformal polymer layer encasing the solar module.

In some embodiments, the step of applying a conformal polymer comprises laminating one or more polymer sheets around the solar module.

Some embodiments further comprise heating the solar module to reflow the conformal polymer around the solar module.

In some embodiments, the step of applying a conformal polymer comprises laminating two polymer sheets around an array including the solar module and one or more additional solar modules;

Some embodiments further comprise applying a respective end cap at each end of the array, the end caps including spaced openings adapted to receive respective ends of each solar module, wherein the openings define a predetermined spacing between adjacent ones of the solar modules.

Some embodiments further comprise removing the end caps after the laminating.

In some embodiments, at least one of the group consisting of the step of forming the back contact, the step of forming the absorber layer and the step of forming the front contact layer includes rotating the substrate during the forming. The methods and system described herein may be at least partially embodied in the form of computer-implemented processes and apparatus for practicing those processes. The disclosed methods may also be at least partially embodied in the form of tangible, non-transitory machine readable storage media encoded with computer program code. The media may include, for example, RAMs, ROMs, CD-ROMs, DVD-ROMs, BD-ROMs, hard disk drives, flash memories, or any other non-transitory machine-readable storage medium, wherein, when the computer program code is loaded into and executed by a computer, the computer becomes an apparatus for practicing the method. The methods may also be at least partially embodied in the form of a computer into which computer program code is loaded and/or executed, such that, the computer becomes a special purpose computer for practicing the methods. When implemented on a general-purpose processor, the computer program code segments configure the processor to create specific logic circuits. The methods may alternatively be at least partially embodied in a digital signal processor formed of application specific integrated circuits for performing the methods.

Although the subject matter has been described in terms of exemplary embodiments, it is not limited thereto. Rather, the appended claims should be construed broadly, to include other variants and embodiments, which may be made by those skilled in the art.

What is claimed is:

1. A solar module, comprising:
a cylindrical substrate;
a back contact layer around the substrate;
an absorber layer around the back contact layer;
a buffer layer around the absorber layer;
a front contact layer around the substrate to form a solar module; and
a conformal polymer layer encasing the solar module.

2. The solar module of claim 1, wherein the substrate is a solid rod.

3. The solar module of claim 1, wherein the substrate is a hollow cylindrical tube, and the conformal polymer is excluded from an interior of the hollow cylindrical tube.

4. The solar module of claim 1, wherein the substrate comprises:
a hollow tube; and
a thermally conductive material filling the hollow tube.

5. The solar module of claim 4, wherein the tube comprises soda lime glass, and the thermally conductive material comprises Al₂O₃.

6. A solar panel, comprising:
at least two solar modules, each solar module comprising:
a cylindrical substrate,
a back contact layer around the substrate,
an absorber layer around the back contact layer,
a buffer layer around the absorber layer, and
a front contact layer around the substrate; and
a continuous conformal polymer layer encasing the at least two solar modules.

7. The solar panel of claim 6, wherein each substrate is a solid rod.

8. The solar panel of claim 6, wherein each substrate is a hollow cylindrical tube, and the conformal polymer is excluded from an interior of each hollow cylindrical tube.

9. The solar panel of claim 6, wherein each substrate comprises:
a hollow tube; and
a thermally conductive material filling the tube.

10. The solar panel of claim 9, wherein each tube comprises soda lime glass, and the thermally conductive material comprises Al₂O₃.

11. The solar panel of claim 6, further comprising a conductor connecting a front electrode of a first one of the solar modules to a back electrode of a second one of the solar modules adjacent to the first solar module, the conductor encased within the conformal polymer layer.

12. The solar panel of claim 6, wherein each adjacent pair of solar modules within the at least two solar modules are separated from each other by a space, and the conformal polymer material fills the space.

13. The solar panel of claim 6, wherein two solar modules within the at least two solar modules have the front electrodes thereof contacting each other.

14. A method, comprising:
forming a back contact layer around a cylindrical substrate;
forming an absorber layer around the back contact layer;
forming a buffer layer around the absorber layer;
forming a front contact layer around the substrate to form a solar module; and
applying a conformal polymer layer encasing the solar module.

15. The method of claim 14, wherein the step of applying a conformal polymer comprises laminating one or more polymer sheets around the solar module.

16. The method of claim 15, further comprising heating the solar module to reflow the conformal polymer around the solar module.

17. The method of claim 14, wherein the step of applying a conformal polymer comprises laminating two polymer sheets around an array including the solar module and one or more additional solar modules;

18. The method of claim 17, further comprising applying a respective end cap at each end of the array, the end caps including spaced openings adapted to receive respective ends of each solar module, wherein the openings define a predetermined spacing between adjacent ones of the solar modules.

19. The method of claim 18, further comprising removing the end caps after the laminating.

20. The method of claim 14, wherein at least one of the group consisting of the step of forming the back contact, the step of forming the absorber layer and the step of forming the front contact layer includes rotating the substrate during the forming.
